(19) United States
(12) Patent Application Publication
(10) Pub. No.: US 2008/0222463 A1
(43) Pub. Date: Sep. 11, 2008

(54) APPARATUS, METHOD AND PRODUCT FOR TESTING COMMUNICATIONS COMPONENTS

(75) Inventors: Rangaprabhu Parthasarathy, Collegeville, PA (US); Dolores F. Howry, Wayne, PA (US); Jeffrey T. Davis, Doylestown, PA (US); Scott C. Hergenhan, Collegeville, PA (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 12/042,132

(22) Filed: Mar. 4, 2008

Related U.S. Application Data
(60) Provisional application No. 60/892,993, filed on Mar. 5, 2007.

(51) Int. Cl. G01R 31/28

(52) U.S. Cl. 714/712

(57) ABSTRACT

An apparatus, method and product for independently testing communications components are disclosed. A testing apparatus is provided that has a test control component which includes an input configured to receive a test script, an upper interface coupling and a lower upper interface coupling. In operation, a protocol stack component to be tested is coupled to the test control component via upper and lower interfaces.

### CROSS REFERENCE TO RELATED APPLICATIONS

This application claims the benefit of U.S. provisional application No. 60/892,993 filed Mar. 5, 2007, which is incorporated by reference as if fully set forth.

### FIELD OF INVENTION

This application is related to apparatus, method and product for testing communications components. More specifically, the disclosed invention relates to the testing of isolated communications components in an environment that simulates the real world operational environment and is particularly useful in testing protocol stack components used in wireless transmit receive units (WTRUs), in terms of software and hardware, in which the software being tested will actually execute and function.

### BACKGROUND

Various communication devices are well known in the art. Modern electronic communications generally employ digitization of communication data and commands which are communicated via selected formats and protocols and/or stacks of protocols. For example, wireless transmit receive units (WTRUs), such as mobile phones, process communication signals that include communication data and commands in specific formats and using components that implement specific protocol stacks in accordance with various standards for the type of system in which the WTRU is designed to operate.

Typically, the processing components are implemented through the use of software or Application Specific Integrated Circuits (ASICs) which are configured to implement a given component of a protocol stack or, as is often the case, several or all components of a given protocol stack for a WTRU or other communication device. In order to improve efficiency, implement new functionality, or comply with revised standards, protocol stack and other processing components for communication data and commands need to be revised or replaced. However, before installing the new or revised components in WTRUs or other communication devices, it is desirable to test the functionality of the components to assure a sufficient level of operating performance.

Historically, protocol stack components and various other communication processing components have been very difficult to test. This is especially true with protocol stacks that are divided into many different components or subcomponents that are intended to operate in many different devices, and where the components and the devices interact with each other and with other software and other devices. For example, WTRUs, which are configured to operate in accordance with GSM, 3GPP, 802.11 and/or other common standards, utilize such multi-component, interactive protocol stacks for processing communication signals. Thus, an apparatus, method and product for testing such communications components is desirable.

### SUMMARY

An apparatus, method and product for independently testing communications components are disclosed. A testing apparatus is provided that has a test control component which includes an input configured to receive a test script, an upper interface coupling and a lower upper interface coupling. In operation, a protocol stack component to be tested is coupled to the test control component via upper and lower interfaces.

The upper interface coupling is preferably configured to direct test signaling to an upper end of a protocol stack component being tested via an upper interface and to receive responsive test signaling from the upper end of the protocol stack component being tested via the upper interface The lower interface coupling is preferably configured to direct test signaling to a lower end of the protocol stack component being tested via a lower interface and to receive responsive test signaling from the lower end of the protocol stack component being tested via the lower interface. The test control component is preferably configured to process a received test script to test the protocol stack component in any combination of sending and receiving test signaling with respect to the upper and lower interfaces.

Preferably, a testing apparatus is provided that is configured to test a protocol stack component for a wireless transmit receive unit (WTRU). The upper interface coupling is then configured to direct internal WTRU test signaling to the upper end of the protocol stack component being tested via the upper interface and to receive responsive internal WTRU signaling from the upper end of the protocol stack component being tested via the upper interface. The lower interface coupling is then configured to direct external WTRU test signaling to the lower end of the protocol stack component being tested via the lower interface and to receive responsive external WTRU signaling from the lower end of the protocol stack component being tested via the lower interface.

### BRIEF DESCRIPTION OF THE DRAWINGS

A more detailed understanding may be had from the following description, given by way of example in conjunction with the accompanying drawings.

FIG. 1 is a block diagram of the components of a test apparatus configuration including a communications component for a wireless transmit/receive unit (WTRU) that is being tested.

FIG. 2 is a block diagram of test script data process flow in the test control component of the apparatus of FIG. 1 for communicating test data simulating external and/or internal WTRU communications to the communications component being tested.

FIG. 3 is a block diagram of a test script data process flow in the test control component of the apparatus of FIG. 1 of external and/or internal responsive WTRU communications from the communications component being tested.

### DETAILED DESCRIPTION

When referred to hereafter, the terminology “wireless transmit/receive unit (WTRU)” includes but is not limited to a user equipment (UE), a mobile station, a fixed or mobile subscriber unit, a pager, a cellular telephone, a personal digital assistant (PDA), a computer, or any other type of user device capable of operating in a wireless environment. When referred to hereafter, the term communications component is the implementation of one or more specific processing functions of communication data or commands. Such components may comprise a portion of a processor that implements many communications components through, for example, software encoding of a specific function or purpose of the communications component.

In general, communication components of a WTRU must process communications signals to and from other devices (“external” WTRU communications) which are received and transmitted via a “physical” layer (L1) of the WTRU which is the base or bottom layer of a typical WTRU protocol stack. Various communication components must also reliably process communications signals to and from other higher layer components within the WTRU (“internal” WTRU communications) as well.

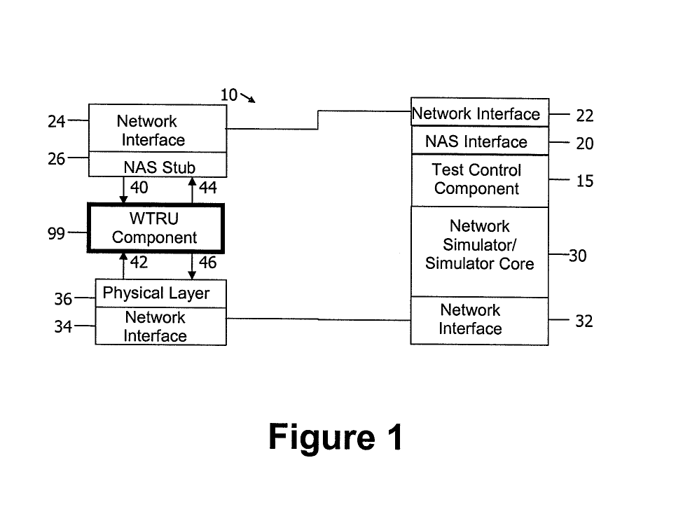

As an example, the testing of a communications component of a protocol stack for a WTRU is provided. The specific example is directed to a combined layer 2-layer 3 (L2/L3) subcomponent within the WTRU component 99 illustrated in FIG. 1. It will be recognized by those skilled in the art that this example is not limiting and the teachings of the present application extend to other implementations that fall within the scope of this disclosure.

In the example embodiment depicted in FIGS. 1-3, the testing apparatus 10 is configured for testing of a communications component 99 of a protocol stack for a WTRU. Preferably, the testing apparatus 10 employs information elements (IEs) of Abstract Syntax Notation number One (ASN.1), an international standard used in communication protocols for conducting testing.

The use of an Extensible Markup Language (XML) test script that defines test commands (comprising raw/text data and ASN.1 IEs), incorporates requisite “include” files, “define” files and “use_defines” is well known in the art. Such test scripts may be manually or semi-automatically created with the assistance of an external tool to communicate the appropriate commands (comprising raw/text data and ASN.1 IEs) for a desired test of a particular component. Typically, ASN.1 IEs are converted into XML by an automated external tool.

The testing apparatus can be implemented on a standard personal computer (PC) running an operating system such as the Windows® operating system, LINUX, etc. The testing apparatus is preferably configured to simulate all of the interfaces required to test a given component of the WRTU software stack with respect to both internal and external WTRU communications. As such, the testing apparatus environment is logically divided into a layered architecture. Upper interface components are provided to interface with an upper end of a test stack component with respect to internal WTRU communications. Lower interface components are provided to interface with a lower end of a test stack component with respect to external WTRU communications. A test control component being provided to control the upper and lower interface components.

In the example depicted in FIG. 1, the testing apparatus 10 comprises a test control component 15 coupled with upper interface components 20, 22, 24, 26 and lower interface components 30, 32, 34, 36. The test control component 15 is configured to execute the test scripts, internal configuration commands and ASN.1 code.

The upper interface components of the example testing apparatus 10 preferably include a Non Access Stratum (NAS) interface 20, a local Network Interface 22, a remote Network Interface 24 and a NAS stub 26 configured to interface with the upper end of a communications component to be tested such as an L2/L3 WTRU component 99. The lower interface components of the example testing apparatus 10 preferably include a Network Simulator/Network Simulator Core interface 30, a local Network Interface 32, a remote Network Interface 34 and Physical Layer (UPHYC) interface 36 configured to interface with the lower end of the communications component to be tested such as L2/L3 WTRU component 99.

The Non Access Stratum (NAS) interface 20, NAS stub 26, Network Simulator/Network Simulator Core interface 30, and Physical Layer (UPHYC) interface 36 are preferably each of conventional design. In one example, an off-the-shelf (OTS) software module from Anite plc was used as the NAS stub 26 and a complementary coded software module was used as the Non Access Stratum (NAS) interface 20 as upper interface components. For lower interface components, an OTS product, Anite SAT[H], from Anite plc was used as the Network Simulator/Network Simulator Core interface 30 and a complementary coded software module was used as the Physical Layer (UPHYC) interface 36.

The local Network Interfaces 22, 32 and remote Network Interface 24, 34 are also of conventional design and are configured to enable remote testing of the communications component to be tested such as L2/L3 WTRU component 99. Accordingly, this enables the test control component 15 to be physically embodied in a local unit and to conduct tests using a physically separate remote unit of the testing apparatus 10 where the remote unit implements the remote Network Interfaces 24, 34, the NAS stub 26 and the Physical Layer (UPHYC) interface 36. Alternatively, the Network Interfaces 22, 32, 24, 34 can be eliminated and the entire test apparatus may be implemented within a unitary testing unit.

The example testing apparatus 10 is configured to send internal WTRU test signaling from the testing control component 15 through the upper interface components 20, 22, 24, 26 via a coupling path 40 to the WTRU stack component 99 being tested. The example testing apparatus 10 is configured to send external WTRU test signaling from the testing control component 15 through the lower interface components 30, 32, 34, 36 via a coupling path 42 to the WTRU stack component 99 being tested.

In response to WTRU test signaling from the testing control component 15, the WTRU stack component 99 will provide either internal or external responsive WTRU signaling. The testing control component 15 is configured to receive responsive internal WTRU test signaling from the WTRU stack component 99 via a coupling path 44 through the upper interface components 20, 22, 24, 26. The testing control component 15 is configured to receive responsive external WTRU test signaling from the WTRU stack component 99 via a coupling path 46 through the lower interface components 30, 32, 34, 36.

In the operation of the testing apparatus 10, the effect of either internal or external WTRU signaling or both can be made on a WTRU L2/L3 combined stack component 99 to evoke either internal or external responsive WTRU signaling or both. Accordingly, the apparatus 10 is configured to process a received test script to test the protocol stack component 99 by any one of the following nine manners:
directing test signaling to the upper end of the protocol stack component 99 via the upper interface and receiving responsive test signaling from the upper end of the protocol stack component 99 tested via the upper interface;
directing test signaling to the upper end of the protocol stack component 99 via the upper interface and receiving responsive test signaling from the lower end of the protocol stack component 99 via the lower interface;
directing test signaling to the upper end of the protocol stack component 99 via the upper interface and receiving responsive test signaling from both the upper end of the protocol stack component 99 via the upper interface and the lower end of the protocol stack component 99 via the lower interface;
directing test signaling to both the upper end of the protocol stack component 99 via the upper interface and the lower end of the protocol stack component 99 via the lower interface and receiving responsive test signaling from the upper end of the protocol stack component 99 via the upper interface;
directing test signaling to both the upper end of the protocol stack component 99 via the upper interface and the lower end of the protocol stack component 99 via the lower interface and receiving responsive test signaling from the lower end of the protocol stack component 99 via the lower interface;
directing test signaling to both the upper end of the protocol stack component 99 via the upper interface and the lower end of the protocol stack component 99 via the lower interface and receiving responsive test signaling from both the upper end of the protocol stack component 99 via the upper interface and the lower end of the protocol stack component 99 via the lower interface;
directing test signaling to the lower end of the protocol stack component 99 via the lower interface and receiving responsive test signaling from the upper end of the protocol stack component 99 via the upper interface;
directing test signaling to the lower end of the protocol stack component 99 via the lower interface and receiving responsive test signaling from the lower end of the protocol stack component 99 via the lower interface; and
directing test signaling to the lower end of the protocol stack component 99 via the lower interface and receiving responsive test signaling from both the upper end of the protocol stack component 99 via the upper interface and the lower end of the protocol stack component 99 via the lower interface.

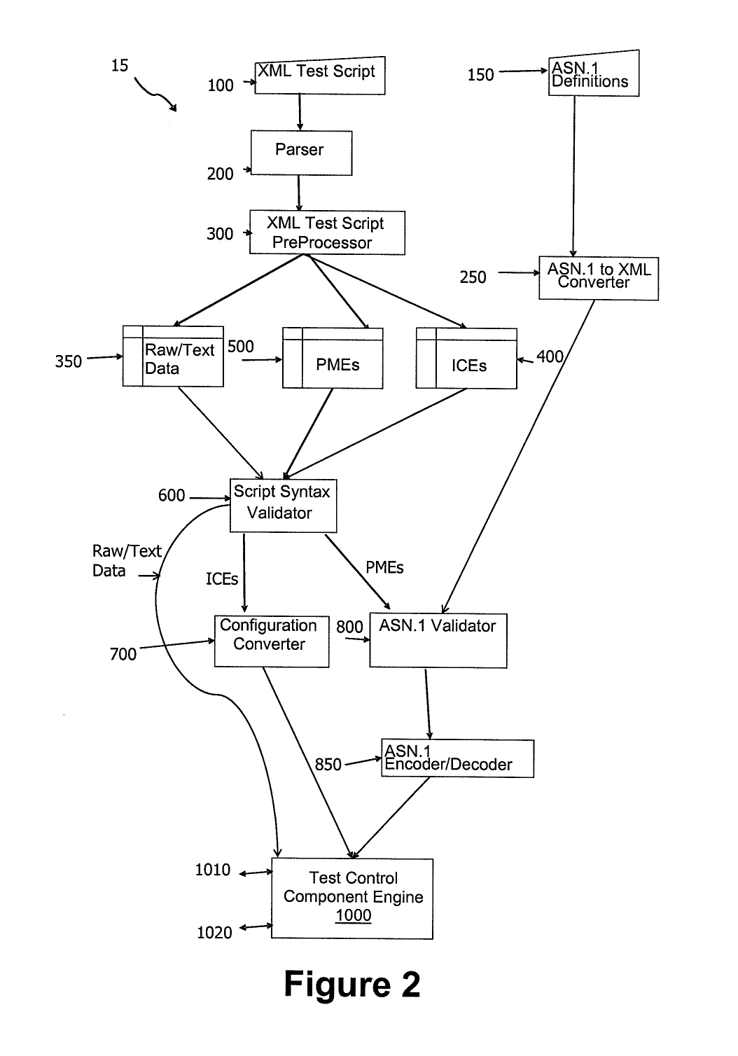

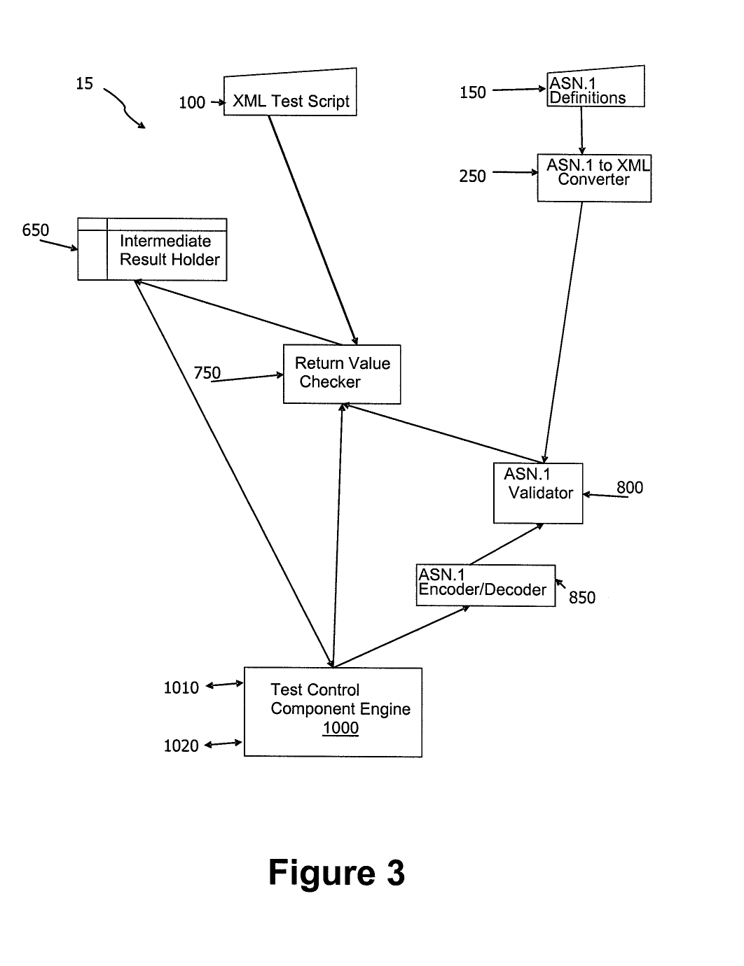

Test script processing in a preferred configuration of the testing control component 15 is described below with respect to FIGS. 2 and 3. FIG. 2 is a block diagram of test script data process flow in the testing control component 15 of the apparatus 10 of FIG. 1 for communicating test data simulating internal and/or external WTRU signaling to the communications component 99 being tested.

The example testing control component 15 is configured to process an XML test script that contains specific test commands, data and internal configuration parameters. The data may be, for example, data to drive an application layer process like a WTRU internet browser. The internal configuration parameters may be, for example, network setup commands.

Referring to FIG. 2, a preferred structure of the example testing control component 15 is represented. An input device 100 is provided to receive an XML test script. Such XML test scripts typically will contain test commands that include raw/text data and/or ASN.1 IEs, “include” files, “define” files and “use_defines” for a desired test of a particular component. A Parser 200 receives the test script from the input device 100. The parser 200 is preferably configured to parse a test script and expand all “includes”, “defines”, and “use_defines” resulting in a flat XML file with no external references which is passed to a Test Script PreProcessor 300. The Test Script PreProcessor 300 is configured to split the flat XML file into three logical data streams, one for raw/text data elements 350, one for peer message elements (PME) 400 and one for internal configuration elements (ICE) 500. The logical data streams are preferably processed by a Script Syntax Validator 600 to insure that they contain properly formatted XML.

The validated raw/text data is passed directly to the Test Control Component Engine 1000 for execution and selective output from an upper interface coupling 1010 and/or a lower interface coupling 1020, depending upon the test which is the subject of the test script being processed. The Validated ICEs are passed to a Configuration Converter 700 that is configured to convert them to an internal data structure for the Test Control Component Engine 1000. The converted, validated ICEs are then passed to the Test Control Component Engine 1000 for execution and selective output from the upper interface and/or lower interface couplings 1020, to control the configuration of the upper and lower interfaces, respectively, depending upon the test which is the subject of the test script being processed.

The validated PME 500 stream is preferably passed to an ASN.1 Validator 800 that is configured to further validate the PMEs to insure proper ASN.1 conformance. The ASN.1 Validator 800 is preferably regularly updated with current ASN.1 information element (IE) definitions. To do this, a component 150 for receiving updated ASN.1 definitions for IEs 150 from a given standard, such as 3GPP Technical Specification (TS) 25.331, is provided along with an ASN.1 to XML Converter 250. The ASN.1 to XML Converter 250 is configured to retrieve the updated ASN.1 definitions, convert the to XML and then sent them to the ASN.1 Validator 800. The ASN.1 Validator 800 is configured to then validate PMEs, which are in XML format, against the most recent updated definitions. The doubly validated PMEs are preferably passed from the ASN.1 Validator to an ASN.1 encoder/decoder 850 that converts the XML PMEs into ASN.1 numerical messages (codes) that are passed to the Test Control Component Engine 1000 for execution and selective output from the upper and/or lower interface couplings 1010, 1020, along with respective raw/text data as test signaling depending upon the test which is the subject of the test script being processed. The WRTU Component 99 being tested will accordingly receive the test signaling through the upper interface and/or lower interface as configured per the respective ICEs in accordance with the test script being processed and then respond to the test signaling.

In response to test script signaling as generated as set forth above with reference to FIG. 2, the WRTU component 99 being tested will be expected to generate responsive signaling through its upper and/or lower ends depending upon the test which is the subject of the test script being processed. Conceivably, a test script could be processed which anticipates no response from the WRTU component 99 being tested, in which case the generation of a response by the test component could indicate a failed result, but generally test scripts are written with the intent to elicit a specific response from the test component.

FIG. 3 is a block diagram of the components of the example test control component 15 of the apparatus of FIG. 1 that are used in processing responsive signaling from the WRTU component 99 being tested. The Test Control Component Engine 1000 is configured to receive a response or responses that may contain raw/text data and/or numerically encoded ASN.1 IEs via either the upper or lower interface couplings 1010, 1020.

Any raw/text data contained in the responsive signals is passed directly to a Return Value Checker (RVC) 750. Any encoded ASN.1 IEs in the responsive signals are passed to the ASN.1 encoder/decoder 850 which converts the ASN.1 numerical codes of response signals into XML ASN.1 IEs. The XML ASN.1 IEs are validated to insure proper ASN.1 conformance by the ASN.1 Validator 800 which is configured to use the most recently updated ASN.1 information element (IE) definitions 150 as described above with reference to FIG. 2. Validated response XML ASN.1 IEs are then passed to the Return Value Checker (RVC) 750.

The Return Value Checker (RVC) 750 receives expected response values from the test script input device as part of a particular test script. All response values passed to the Return Value Checker (RVC) 750 resulting from processing the particular test script are then checked to determine if they match the return value(s) expected by the test script. If a given value matches a result expected by the test script, it is stored as a “pass” in an intermediate result holder 650, if it does not match, a fail indication is stored in the intermediate result holder 650. The absence of an expected response or the receipt of unexpected responses are also preferably noted, preferably as different classifications of test failure.

Preferably, results are processed and stored in the intermediate result holder 650 until the test script has terminated the generation of test signaling and a sufficient period for responsive signals to be received has elapsed, i.e. test script completion. Alternatively, the test control component can be configured to selectively return intermediate results to the Test Control Component Engine 1000 where a test script is written to require certain intermediate results for a determination of how the testing is to proceed at a certain interim point. Test scripts may define continuance and/or discontinuance of the generation of further test signaling based upon positive and/or negative interim test results.

Upon test script completion, the intermediate result holder 650 preferably transfers all pass/fail information to a graphical user interface contained in the Test Control Component Engine 1000. The graphical user interface of the Control Component Engine 1000 may also be configured to provide monitoring information to track the progress of a test script while the testing is being conducted.

The following is an example of the execution of a test script in the testing apparatus 15 to test the impact (if any) of a change to a Medium Access Control (MAC-layer 2) layer component for a WTRU. A combined layer 2-layer 3 component having the modified MAC is provided as the WTRU component 99. A test script is written to first provide a higher layer WTRU signal that is intended to generate a WTRU transmission and receive an acknowledgement of success. The XML test script contains appropriate test commands comprising raw/text data and/or ASN.1 IEs, “include” files, “define” files and “use_defines” to generate upper interface signaling simulating the WTRU's internal higher layer signaling as well as to generate lower interface signaling simulating the expected acknowledgement. The test script also contains the expected results of the test component's responses to the respective upper and lower layer interface test signaling.

The XML test script is input to the input device 100 of the Test Control Component 15 which processes them as explained in connection with FIG. 2 and outputs the test signaling to the upper end of the WRTU test component 99 through the upper interface components and coupling path 40 to simulate the higher layer WTRU signal. The test component 99 generates responsive signals which are communicated back to the Test Control Component 15 and processed as explained in connection with FIG. 2 and lower interface. Assuming the test script anticipated responsive signaling of predetermined data and ASN.1 codes via path 46 through the lower interface components, if such responsive signaling is received, an interim “pass” result is recorded by the intermediate result holder 650.

In accordance with the XML test script, the Test Control Component 15 may subsequently output test signaling to the lower end of the WRTU test component 99 through the lower interface components and coupling path 42 to simulate the acknowledgement signaling. The Test Control Component 15 is preferably configured to rely upon the generation of the intermediate result before the subsequent signaling and to permit the test script to indicate whether or not the testing should continue if selected “passes” or “fails” have or have not been generated. In response to subsequent test signaling, the test component 99 generates responsive signals which are communicated back to the Test Control Component 15 and processed as explained in connection with FIG. 2. Assuming the test script anticipated responsive signaling for the subsequent test signaling of predetermined data and ASN.1 codes via path 44 through the upper interface components, if such responsive signaling is received, an interim “pass” result is recorded by the intermediate result holder 650. If the testing is then completed, all of the interim results are then preferably passed to the graphics display and/or other user output of Test Control Component 15.

The testing of components in accordance with the testing apparatus and methods described above are particularly useful in designing new and/or improved protocol stack components for WTRUs. Accordingly, new and/or improved WTRUs are provided by constructing WTRUs using protocol stack components designed through testing using the testing apparatus and/or methods disclosed herein.

Although the features and elements of the present invention are described in the preferred embodiments in particular combinations, each feature or element can be used alone without the other features and elements of the preferred embodiments or in various combinations with or without other features and elements of the present invention. The test control apparatus and, in particular, the test control component may be implemented in a computer program, software, or firmware tangibly embodied in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Components designed through the use of the above disclosed testing apparatus and methods may be embodied in a processor. Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

A processor in association with software may be used to implement a radio frequency transceiver for use in a wireless transmit receive unit (WTRU), user equipment (UE), terminal, base station, radio network controller (RNC), or any host computer. The WTRU may be used in conjunction with modules, implemented in hardware and/or software, such as a camera, a video camera module, a videophone, a speakerphone, a vibration device, a speaker, a microphone, a television transceiver, a hands free headset, a keyboard, a Bluetooth® module, a frequency modulated (FM) radio unit, a liquid crystal display (LCD) display unit, an organic light-emitting diode (OLED) display unit, a digital music player, a media player, a video game player module, an Internet browser, and/or any wireless local area network (WLAN) module.

What is claimed is:

1. A testing apparatus comprising a test control component including:
an input configured to receive a test script;
an upper interface coupling configured to direct test signaling to an upper end of a protocol stack component being tested via an upper interface and to receive responsive test signaling from the upper end of the protocol stack component being tested via the upper interface; and
a lower interface coupling configured to direct test signaling to a lower end of the protocol stack component being tested via a lower interface and to receive responsive test signaling from the lower end of the protocol stack component being tested via the lower interface; and
the test control component configured to process a received test script to test the protocol stack component being tested by any one of the following manners:
directing test signaling to the upper end of the protocol stack component being tested via the upper interface and receiving responsive test signaling from the upper end of the protocol stack component being tested via the upper interface;
directing test signaling to the upper end of the protocol stack component being tested via the upper interface and receiving responsive test signaling from the lower end of the protocol stack component being tested via the lower interface;
directing test signaling to the upper end of the protocol stack component being tested via the upper interface and receiving responsive test signaling from both the upper end of the protocol stack component being tested via the upper interface and the lower end of the protocol stack component being tested via the lower interface;
directing test signaling to both the upper end of the protocol stack component being tested via the upper interface and the lower end of the protocol stack component being tested via the lower interface and receiving responsive test signaling from the upper end of the protocol stack component being tested via the upper interface;
directing test signaling to both the upper end of the protocol stack component being tested via the upper interface and the lower end of the protocol stack component being tested via the lower interface and receiving responsive test signaling from the lower end of the protocol stack component being tested via the lower interface;
directing test signaling to both the upper end of the protocol stack component being tested via the upper interface and the lower end of the protocol stack component being tested via the lower interface and receiving responsive test signaling from both the upper end of the protocol stack component being tested via the upper interface and the lower end of the protocol stack component being tested via the lower interface;
directing test signaling to the lower end of the protocol stack component being tested via the lower interface and receiving responsive test signaling from the upper end of the protocol stack component being tested via the upper interface;
directing test signaling to the lower end of the protocol stack component being tested via the lower interface and receiving responsive test signaling from the lower end of the protocol stack component being tested via the lower interface; and
directing test signaling to the lower end of the protocol stack component being tested via the lower interface and receiving responsive test signaling from both the upper end of the protocol stack component being tested via the upper interface and the lower end of the protocol stack component being tested via the lower interface.

2. The testing apparatus of claim 1 configured to test a protocol stack component for a wireless transmit receive unit (WTRU) wherein the upper interface coupling is configured to direct internal WTRU test signaling to the upper end of the protocol stack component being tested via the upper interface and to receive responsive internal WTRU signaling from the upper end of the protocol stack component being tested via the upper interface and the lower interface coupling is configured to direct external WTRU test signaling to the lower end of the protocol stack component being tested via the lower interface and to receive responsive external WTRU signaling from the lower end of the protocol stack component being tested via the lower interface.

3. The testing apparatus of claim 2 further comprising the upper interface and the lower interface.

4. The testing apparatus of claim 3 wherein the upper interface includes an internal WTRU signaling simulation component configured to interface with the upper end of the protocol stack component being tested and the lower interface includes an external WTRU signaling simulation component configured to interface with the lower end of the protocol stack component being tested.

5. The testing apparatus of claim 4 comprising a local unit that includes the test control component and a remote unit that includes the internal WTRU signaling simulation component and the external WTRU signaling simulation component wherein the upper and lower interfaces each include a local Network Interface component disposed in the local unit and a remote Network Interface component disposed in the remote unit to thereby enable remote testing of the protocol stack component being tested.

6. A protocol stack component for a wireless transmit receive unit designed through testing on the testing apparatus of claim 4.

7. A wireless transmit receive unit comprising a protocol stack component designed through testing on the testing apparatus of claim 4.

8. A the protocol stack component for a wireless transmit receive unit designed through testing on the testing apparatus of claim 2.

9. A wireless transmit receive unit comprising a protocol stack component designed through testing on the testing apparatus of claim 2.

10. The testing apparatus of claim 1 further comprising the upper interface and the lower interface.

11. The testing apparatus of claim 10 configured to test a combined layer 2-layer 3 component for a wireless transmit receive unit wherein the upper interface includes a NAS stub component configured to interface with an upper end of a combined layer 2-layer 3 component being tested and the lower interface includes a physical layer simulation component configured to interface with a lower end of the combined layer 2-layer 3 component being tested.

12. The testing apparatus of claim 11 comprising of a local unit that includes the test control component and a remote unit that includes the NAS stub component and the physical layer simulation component wherein the upper and lower interfaces each include a local Network Interface component disposed in the local unit and a remote Network Interface component disposed in the remote unit to thereby enable remote testing of the combined layer 2-layer 3 component being tested.

13. A combined layer 2-layer 3 component for a wireless transmit receive unit designed through testing on the testing apparatus of claim 11.

14. A wireless transmit receive unit comprising a combined layer 2-layer 3 component designed through testing on the testing apparatus of claim 11.

15. The testing apparatus of claim 1 configured to test a combined layer 2-layer 3 component for a wireless transmit receive unit wherein the upper interface coupling is configured to direct internal WTRU test signaling to the upper end of a combined layer 2-layer 3 component being tested via the upper interface and to receive responsive internal WTRU signaling from the upper end of the combined layer 2-layer 3 component being tested via the upper interface and the lower interface coupling is configured to direct external WTRU test signaling to the lower end of the combined layer 2-layer 3 component being tested via the lower interface and to receive responsive external WTRU signaling from the lower end of the combined layer 2-layer 3 component being tested via the lower interface.

16. A combined layer 2-layer 3 component for a wireless transmit receive unit designed through testing on the testing apparatus of claim 15.

17. A wireless transmit receive unit comprising a combined layer 2-layer 3 component designed through testing on the testing apparatus of claim 15.

18. The testing apparatus of claim 1 wherein the test control component is configured to receive extensible markup language (XML) test scripts and comprises:
a test control component engine configured to control the upper and lower test control component interfaces;
a parser configured to parse an XML test script and expand include files, define files and use_defines resulting in a flat test script;
a test script pre-processor configured to separate data statements, internal configuration element statements and peer message element statements of the flat test script into a separate logical data streams;
a test script syntax validator configured to validate that the logical data streams contain properly formatted XML statements;
a configuration converter configured to convert internal configuration element statements of a logical data stream into a test control component engine data structure;
an abstract syntax language one (ASN.1) validator configured to validate that peer message element statements of a logical data stream conform with a desired ASN.1 format;
an ASN.1 encoder/decoder configured to encode ASN.1 information elements in validated peer message element statements into numerical code for execution by the test control component engine and configured to decode numerical ASN.1 information elements into an XML ASN.1 information element statement; and
the test control component engine configured to execute XML statements of the logical data streams received from the test script syntax validator, the configuration converter and the ASN.1 encoder/decoder to send test signaling through the upper and lower interface couplings; and
the test control component engine configured to receive responsive test signaling through the upper and lower interface couplings and to direct numerical ASN.1 information elements contained in responsive test signaling to the ASN.1 encoder/decoder.

19. The testing apparatus of claim 16 wherein the test control component further comprises:
a return value checker configured to receive test results contained in responsive test signaling from the test control component engine and in decoded numerical ASN.1 information elements from the ASN.1 encoder/decoder and configured to compare such test results with expected values generated from the XML test script; and
a memory associated with the return value checker configured to store comparative test result data.

20. A protocol stack component for a wireless transmit receive unit designed through testing on the testing apparatus of claim 19.

21. A wireless transmit receive unit comprising a protocol stack component designed through testing on the testing apparatus of claim 19.

22. A method for testing a protocol stack component comprising:
processing a test script to direct test signaling to an upper end of the protocol stack component being tested and/or to direct test signaling to the lower end of the protocol stack component being tested;
receiving responsive signaling from the upper end of the protocol stack component being tested and/or receiving responsive signaling from the lower end of the protocol stack component being tested; and
evaluating the received responsive signaling in accordance with parameters defined by the processed test script.

23. The method for testing a protocol stack component according to claim 22 wherein:
a test script is processed to direct test signaling to an upper end of the protocol stack component being tested and to direct test signaling to the lower end of the protocol stack component being tested;
responsive signaling is received from the upper end of the protocol stack component being tested and from the lower end of the protocol stack component being tested.

24. The method for testing a protocol stack component for a wireless transmit receive unit (WTRU) according to claim 22 wherein:
the test script is processed to direct internal WTRU test signaling to an upper end of the protocol stack component being tested and/or to direct external WTRU test signaling to the lower end of the protocol stack component being tested; and
responsive internal WTRU signaling is received from the upper end of the protocol stack component being tested and/or responsive external WTRU signaling is received from the lower end of the protocol stack component being tested.

25. The method for testing a protocol stack component for a wireless transmit receive unit (WTRU) according to claim 22 wherein:
the test script is processed to direct internal WTRU test signaling to an upper end of the protocol stack component being tested and to direct external WTRU test signaling to the lower end of the protocol stack component being tested; and
responsive internal WTRU signaling is received from the upper end of the protocol stack component being tested and responsive external WTRU signaling is received from the lower end of the protocol stack component being tested.

26. The method of claim 22 wherein the processing a test script comprises:
preprocessing the test script to separate data statements, internal configuration element statements and peer message element statements of an XML test script into a separate logical data streams;
validating test script syntax of the separate logical data streams of XML statements;
converting internal configuration element statements of a logical data stream into a test control component engine data structure;
validating that peer message element statements of a logical data stream conform with a desired abstract syntax language one (ASN.1) format;
encoding ASN.1 information elements in validated peer message element statements into numerical code for execution by the test control component engine; and
executing validated data statements and converted internal configuration element statements of the respective logical data streams in connection with numerical code of encoded ASN.1 information elements in validated peer message element statements to generate the test signaling directed to the protocol stack component being tested.

27. The method of claim 26 wherein the evaluating the received responsive signaling comprises:
receiving test results contained in responsive test signaling and comparing such test results with expected values generated from the XML test script; and
storing comparative test result data.

28. The method of claim 26 wherein the evaluating the received responsive signaling comprises:
decoding numerical ASN.1 information elements contained in responsive test signaling into XML ASN.1 information element statements;
validating that the decoded XML ASN.1 information element statements conform with a desired abstract syntax language one (ASN.1) format; and
comparing the validated decoded XML ASN.1 information element statements with expected values generated from the XML test script.

29. The method of claim 26 wherein the validating that peer message element statements of a logical data stream conform with a desired abstract syntax language one (ASN.1) format includes receiving ASN.1 information element (IE) definitions and converting the ASN.1 IE definitions into XML.

30. The method of claim 26 wherein the test script processing further comprises expanding include files, define files and use_defines in the XML test script in advance of preprocessing.

31. An apparatus configured to test software modules comprising:
an input device configured to receive extensible markup language (XML) test scripts;
a parser configured to parse a received XML test script and expand any include files, define files and use_defines resulting in a flat XML test script;
a preprocessor configured to split the flat XML test script into a plurality of logical streams including a first stream for a peer message element (PME) statements, a second stream for an internal configuration element (ICE) statements and a third stream for data statements;
a syntax validator configured to validate that the streams contain properly formatted XML code;
a converter configured to convert an internal configuration element statements into an internal data structure for execution by the test engine;
an abstract syntax language one (ASN.1) validator configured to validate peer message element (PME) statements containing ASN.1 information elements (IEs) for ASN.1 conformance;
an encoder configured to encode validated ASN.1 information element (IE) into ASN.1 numerical code; and
a test engine configured to execute validated data statements and converted internal configuration element statements of the respective logical data streams in connection with numerical code of encoded ASN.1 information elements in validated peer message element statements to generate the test signaling directed to the software module being tested.

32. The apparatus of claim 31 further comprising:
a return value checker configured to receive from the test engine test results contained in responsive test signaling and to compare such test results with expected values generated from the XML test script and
a memory configured to store comparative test result data.

33. The apparatus of claim 31 further comprising:
a decoder configured to decode numerical ASN.1 information elements contained in responsive test signaling into XML ASN.1 information element statements; and
a return value checker configured to compare the decoded XML ASN.1 information element statements with expected values generated from the XML test script.

34. A computer-readable medium having stored thereon sequences of instructions, the sequences of instructions including instructions, when executed by a processor, configured to cause the processor to perform:
processing a test script to direct test signaling to an upper end of the protocol stack component being tested and/or to direct test signaling to the lower end of the protocol stack component being tested;
receiving responsive signaling from the upper end of the protocol stack component being tested and/or receiving responsive signaling from the lower end of the protocol stack component being tested; and
evaluating the received responsive signaling in accordance with parameters defined by the processed test script.

35. The computer-readable medium according to claim 34 wherein the sequences of instructions directed to processing a test script, are configured to cause the processor to perform:
preprocessing the test script to separate data statements, internal configuration element statements and peer message element statements of an XML test script into a separate logical data streams;
validating test script syntax of the separate logical data streams of XML statements;
converting internal configuration element statements of a logical data stream into a test control component engine data structure;
validating that peer message element statements of a logical data stream conform with a desired abstract syntax language one (ASN.1) format;
encoding ASN.1 information elements in validated peer message element statements into numerical code for execution by the test control component engine; and
executing validated data statements and converted internal configuration element statements of the respective logical data streams in connection with numerical code of encoded ASN.1 information elements in validated peer message element statements to generate the test signaling directed to the protocol stack component being tested.

36. The computer-readable medium according to claim 34 wherein the sequences of instructions directed to evaluating the received responsive signaling, are configured to cause the processor to perform:
receiving test results contained in responsive test signaling and comparing such test results with expected values generated from the XML test script; and
storing comparative test result data.

37. The computer-readable medium according to claim 34 wherein the sequences of instructions directed to evaluating the received responsive signaling, are configured to cause the processor to perform:
decoding numerical ASN.1 information elements contained in responsive test signaling into XML ASN.1 information element statements;
validating that the decoded XML ASN.1 information element statements conform with a desired abstract syntax language one (ASN.1) format; and
comparing the validated decoded XML ASN.1 information element statements with expected values generated from the XML test script.

38. The computer-readable medium according to claim 37 wherein the sequences of instructions directed to validating decoded XML ASN.1 information element statements, are configured to cause the processor to perform receiving ASN.1 information element (IE) definitions and converting the ASN.1 IE definitions into XML.

39. The computer-readable medium according to claim 34 wherein the sequences of instructions directed to processing a test script, are configured to cause the processor to perform:
expanding include files, define files and use_defines in the XML test script in advance of preprocessing.
